(19) United States
(12) Patent Application Publication
(10) Pub. No.: US 2015/0064905 A1
(43) Pub. Date: Mar. 5, 2015

(54) SEMICONDUCTOR PROCESS

(71) Applicant: UNITED MICROELECTRONICS CORP., Hsin-Chu City (TW)

(72) Inventor: Tsung-Hsun Tsai, Chiayi County (TW)

(73) Assignee: UNITED MICROELECTRONICS CORP., Hsin-Chu City (TW)

(21) Appl. No.: 14/016,233

(22) Filed: Sep. 3, 2013

(51) Int. Cl. H01L 29/66

(52) U.S. Cl. CPC H01L 29/66553
USPC 438/694

(57) ABSTRACT

A semiconductor process including the following steps is provided. A substrate is provided. A nitride layer is formed on the substrate, but exposing a silicon containing area. An oxidation process is performed to oxidize a surface of the silicon containing area to form an oxidized surface. The nitride layer is removed.

### BACKGROUND OF THE INVENTION

1. Field of the Invention

The present invention relates generally to a semiconductor process, and more specifically to a semiconductor process, which removes nitride layers.

2. Description of the Prior Art

In integrated circuit processes, metal-oxide-semiconductor field effect transistors play important roles. Along with the shrinking in size of semiconductor components, the processing steps of transistors to produce high quality transistors have to be adapted to these small sizes.

In general, nitride layers are widely used in nowadays transistor processes. The nitride layers may serve as spacers, stress layers, hard masks or etch stop layers, and the nitride layers may be removed after achieving their original purposes. For example, in current transistor processes, a lightly doped drain (LDD) region, an epitaxial layer or a source/drain region may be formed in a substrate beside a gate after the gate structure is formed on the substrate. However, spacers need to be formed on the substrate beside the gate first to define and form the lightly doped drain (LDD) region, the epitaxial layer or the source/drain region. Then, the spacers are removed. In another way, a stress layer may be covered to enhance the carrier mobility of a gate channel below the gate, and the stress layer is removed after the stresses are memorized in the gate channel by an annealing process.

However, when said nitride layers are removed, other areas from the nitride layers, especially for other silicon areas, will be damaged, thereby causing a degradation of the semiconductor structure to form.

### SUMMARY OF THE INVENTION

The present invention provides a semiconductor process, which solve said problem of damaged silicon containing areas by performing an oxidation process before removing a nitride layer.

The present invention provides a semiconductor process including the following steps. A substrate is provided. A nitride layer is formed on the substrate but exposing a silicon containing area of the substrate. An oxidation process is performed to oxidize a surface of the silicon containing area to form an oxidized surface. The nitride layer is then removed.

According to the above, the present invention provides a semiconductor process, which performs an oxidation process before removing a nitride layer to oxide a silicon containing area other than the nitride layer. Therefore, an oxidized surface is formed on the silicon containing area serving as a protective layer to prevent the silicon containing area from being damaged when removing the nitride layer. Then, the oxidized surface may be removed for performing other semiconductor processes thereafter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 schematically depict cross-sectional views of a semiconductor process according to a first embodiment of the present invention.

FIGS. 8-10 schematically depict cross-sectional views of a semiconductor process according to a second embodiment of the present invention.

### DETAILED DESCRIPTION

A first embodiment is presented for forming a CMOS transistor while a second embodiment is presented for forming a MOS transistor, and the two embodiments are all examples of planar transistors, but it is not limited thereto. In another embodiment, the present invention can also be applied to non-planar transistors, such as multi-gate MOSFETs, or other planar transistors, depending upon the needs.

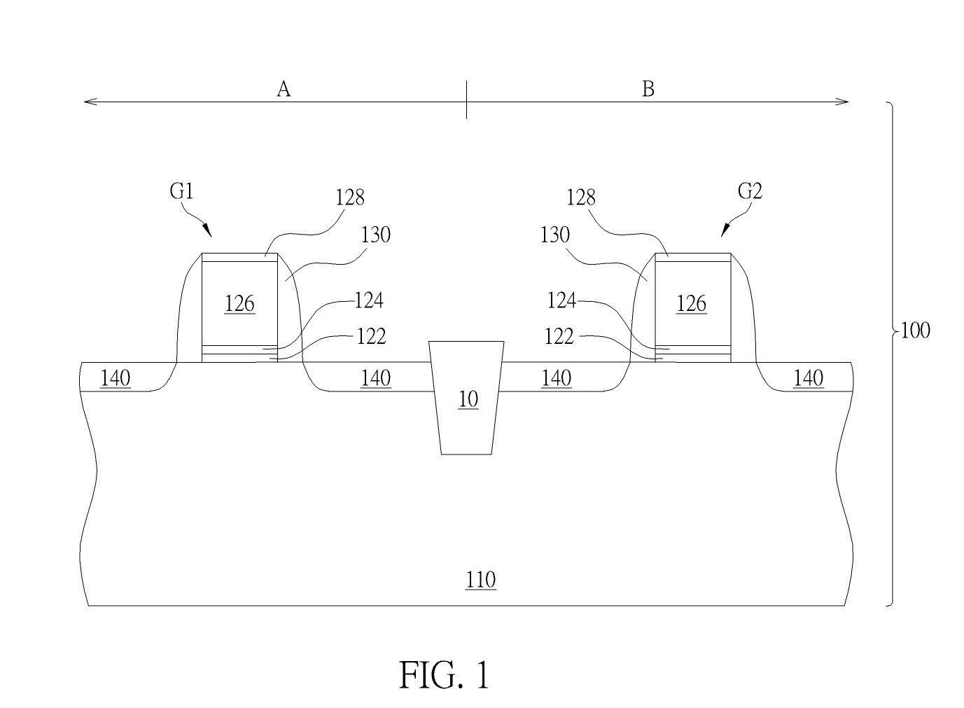

FIGS. 1-7 schematically depict cross-sectional views of a semiconductor process according to a first embodiment of the present invention. As shown in FIG. 1, a substrate 110 is provided. The substrate 110 may be a semiconductor substrate, such as a silicon substrate, a silicon containing substrate, a III-V group-on-silicon (such as GaN-on-silicon) substrate, a graphene-on-silicon substrate or a silicon-on-insulator (SOI) substrate. An isolation structure 10 is formed in the substrate 110, wherein the isolation structure 10 may be a shallow trench isolation (STI) structure, which may be formed by a shallow trench isolation process, but it is not limited thereto. Thus, the substrate 110 can be divided into a first area A and a second area B by the isolation structure 10.

A first gate G1 and a second gate G2 are formed on the substrate 110 of the first area A and the second area B respectively. In this embodiment, the first gate G1 is a gate of a PMOS transistor and the second gate G2 is a gate of an NMOS transistor so that a CMOS transistor 100 is formed, but it is not limited thereto. In another embodiment, the first gate G1 may be a gate of an NMOS transistor while the second gate G2 is a gate of a PMOS transistor.

The steps of forming the first gate G1 and the second gate G2 may include the following. A buffer layer (not shown), a gate dielectric layer (not shown), a barrier layer (not shown), a sacrificial electrode layer (not shown) and a cap layer (not shown) are sequentially formed from bottom to top and cover the substrate 110 of the first area A and the second area B. Then, the cap layer (not shown), the sacrificial electrode layer (not shown), the barrier layer (not shown), the gate dielectric layer (not shown) and the buffer layer (not shown) are patterned to form a buffer layer 122, a gate dielectric layer 124, a barrier layer (not shown), a sacrificial electrode layer 126 and a cap layer 128 on the substrate 110. This means that the first gate G1 in the first area A and the second gate G2 in the second area B including the buffer layer 122, the gate dielectric layer 124, the barrier layer, the sacrificial electrode layer 126 and the cap layer 128 are formed. In this embodiment, there are one first gate G1 and one second gate G2 depicted in the first area A and in the second area B respectively for illustrating the present invention clearly. However, the number of gates in the first area A and in the second area B is not restricted to this, and may vary upon the needs.

The buffer layer 122 may be an oxide layer, which may be formed through a chemical oxidation process or a thermal oxidation process, but it is not limited thereto. The buffer layer 122 is located between the gate dielectric layer 124 and the substrate 110 to buffer the gate dielectric layer 124 and the substrate 110. Since a gate-last for high-k first process is applied in this embodiment, the gate dielectric layer 124 is a gate dielectric layer having a high dielectric constant, which may be the group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁-xO₃, PZT) and barium strontium titanate (BaₓSr₁-xTiO₃, BST), but it is not limited thereto. In another embodiment, wherein a gate-last for high-k last process is applied, the gate dielectric layer 124 is removed in later processes and then a gate dielectric layer having a high dielectric constant is formed. Therefore, the material of the gate dielectric layer 124 may be just a sacrificial material suitable for being removed in later processes. The barrier layer is located on the gate dielectric layer 124 to prevent above disposed metals from diffusing downwards to the gate dielectric layer 124 and from polluting the gate dielectric layer 124. The barrier layer may be a single layer structure or a multilayer structure composed of tantalum nitride (TaN) or titanium nitride (TiN). The sacrificial electrode layer 126 may be made of polysilicon, but it is not limited thereto. The cap layer 128 may be a single layer or a multilayer composed of a nitride layer or an oxide layer etc used as a patterned hard mask, but it is not limited thereto. In this embodiment, the cap layer 128 is a nitride layer, which will be removed while a later process step of removing nitride layers is performed.

A spacer 130 is formed on the substrate 110 beside the first gates G1 and the second gates G2 respectively. The method of forming the spacer 130 may include the following. A spacer material (not shown) is formed to entirely cover the first gates G1, the second gates G2 and the substrate 110. Then, the spacer material is etched to form the spacers 130 on the substrate 110 beside the first gates G1 and the second gates G2 respectively. The spacers 130 may have a single layer or a multilayer composed of nitride or/and oxide. In this embodiment, a lightly doped ion implantation process may be performed to self-align and form a lightly doped source/drain 140 in the substrate 110 beside each of the spacers 130, but it is not limited thereto.

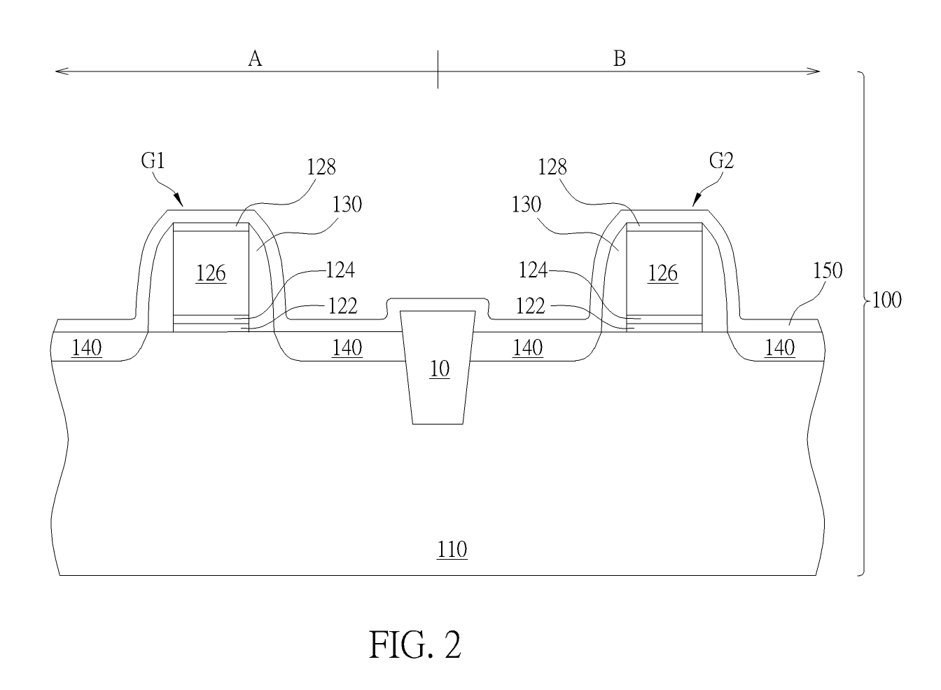

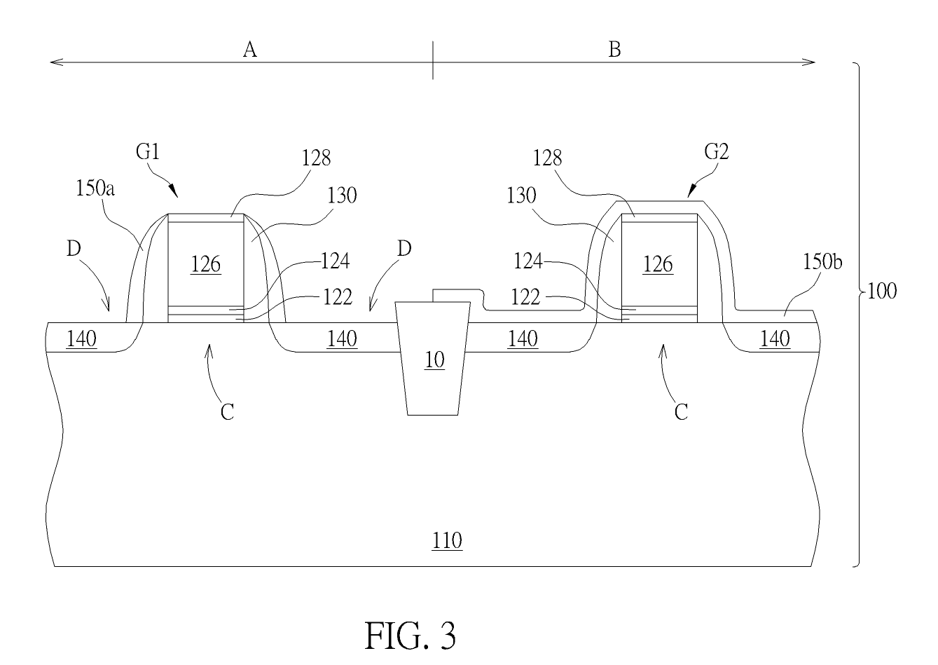

As shown in FIG. 2, a nitride spacer material 150 is formed to entirely cover the first gate G1, the second gate G2 and substrate 110. As shown in FIG. 3, the nitride spacer material 150 covering the first area A, i.e. the nitride spacer material 150 covering the substrate 110 beside the first gate G1, is etched, to form a nitride spacer 150a, while a nitride spacer material 150b covering the second area B, i.e. the nitride spacer material 150b covering the substrate 110 beside the second gate G2, is kept. More precisely, a photoresist (not shown) may cover the second area B. An etching process may be performed to each the nitride spacer material 150 in the first area A to form the nitride spacer 150a. Then, the photoresist is removed. Therefore, the nitride spacer 150a is formed in the first area A while the nitride spacer material 150b is kept in the second area B. The nitride spacer material 150 may be a doped or undoped nitride, and may have the property of inducing stresses in gate channels C below the first gate G1 and the second gate G2, depending upon the needs. Thus, as shown in FIGS. 2-3, a nitride layer is formed on the substrate 110, wherein the nitride layer includes the nitride spacer 150a and the nitride spacer material 150b; the substrate 110 having a silicon containing area D is exposed, wherein the silicon containing area D includes the substrate 110 beside the nitride spacer 150a in the first area A.

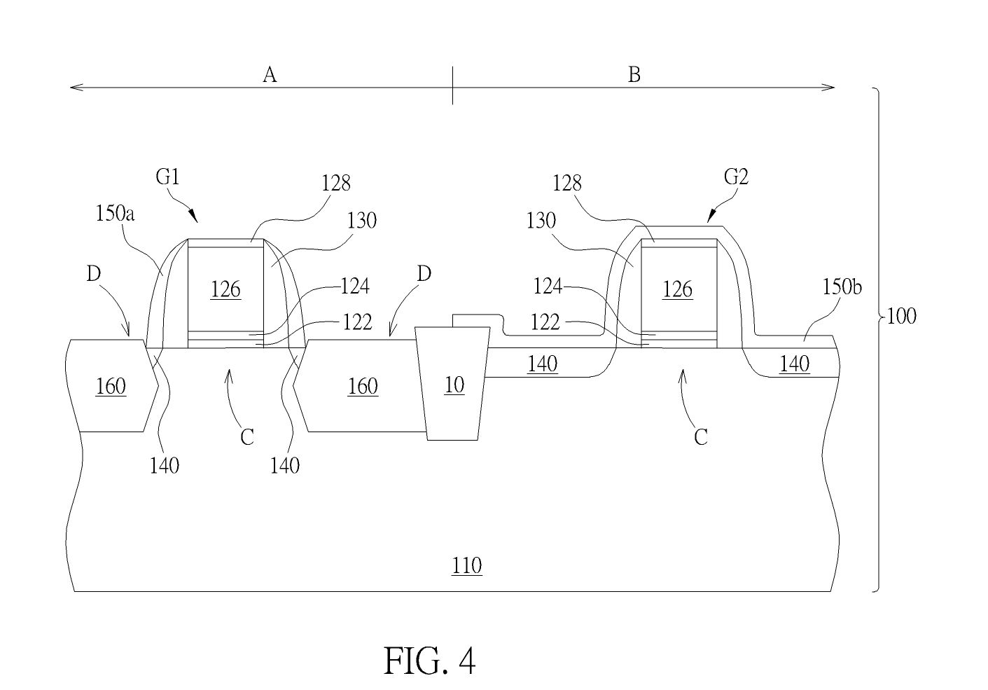

Thereafter, an epitaxial layer, a source/drain region or a metal silicide etc may be formed in/on the substrate 110 beside the nitride spacer 150a. As shown in FIG. 4, an epitaxial layer 160 is formed in the silicon containing area D. In this embodiment, since the first gate G1 is a gate of a PMOS transistor, the epitaxial layer 160 is preferably a silicon germanium epitaxial layer or etc, which is suited for forming an epitaxial layer of a PMOS transistor, but it is not limited thereto.

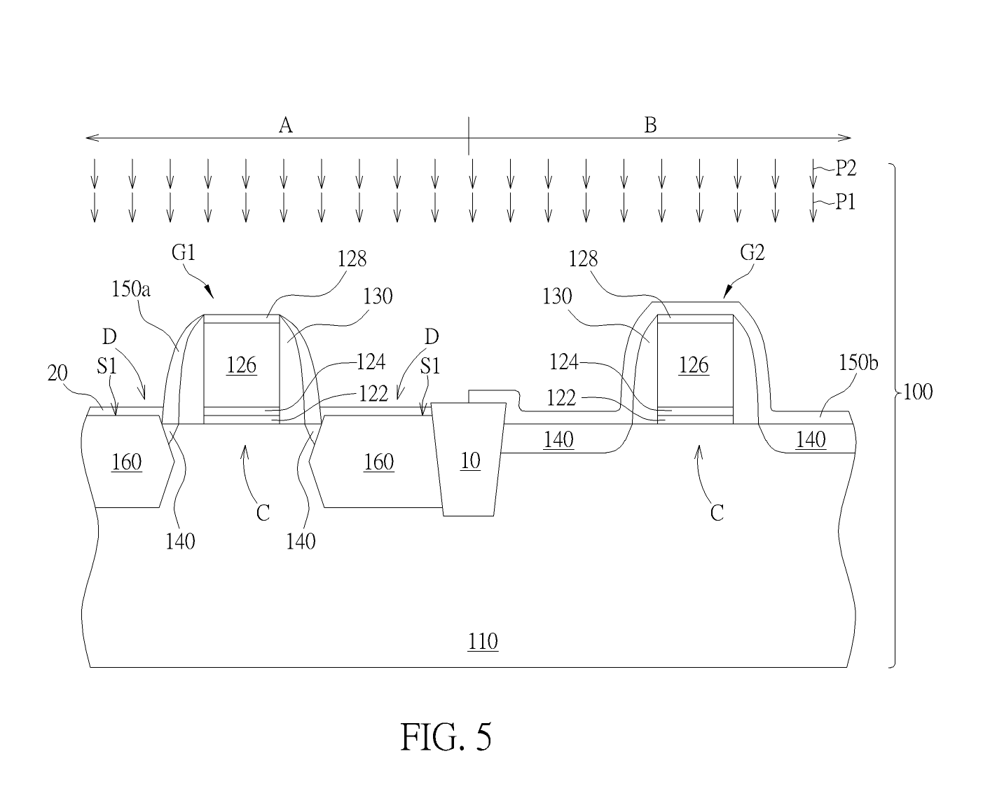

As shown in FIG. 5, a cleaning process P1 may be selectively performed to remove native oxides on the substrate 110, the epitaxial layer 160, the nitride spacer 150a and the nitride spacer material 150b. In this embodiment, the cleaning process P1 is a dilute hydrofluoric acid (DHF) containing cleaning process, but it is not limited thereto. In another embodiment, the cleaning process P1 may include other cleaning processes such as a cleaning process with an acid etchant or a cleaning process with an alkaline etchant.

An oxidation process P2 is performed to oxide a surface S1 of the silicon containing area D or the epitaxial layer 160, therefore an oxidized surface 20 is formed. The oxidation process P2 may be a chemical oxidation process or a thermal oxidation process etc. The oxidation process P2 may be a peroxide containing oxidation process, an ozone containing oxidation process or a plasma oxygen containing oxidation process etc. The oxidized surface 20 can be formed by oxidizing the surface S1 of the silicon containing area D without oxidizing areas other than silicon containing area D such as the nitride spacer 150a and the nitride spacer material 150b through selecting the oxidation process P2. In this embodiment, the oxidized surface 20 is formed by oxidizing the surface S1 of the silicon containing area D. In another embodiment, the oxidized surface 20 may be directly formed on the silicon containing area D without oxidizing it.

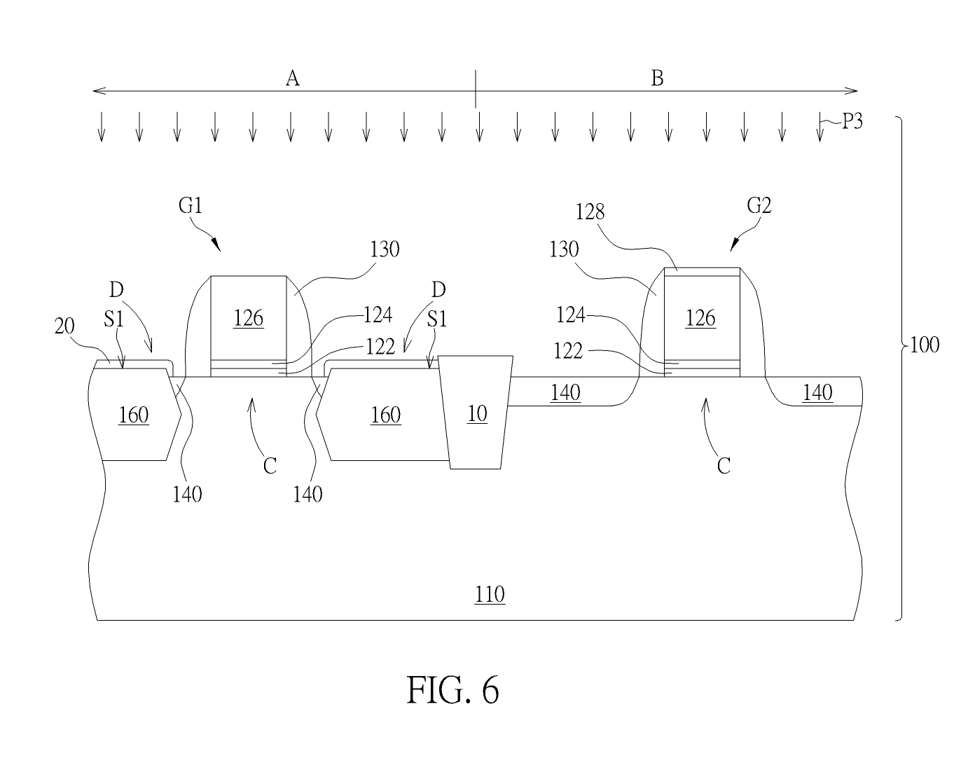

Then, the nitride spacer 150a in the first area A and the nitride spacer material 150b in the second area B are removed simultaneously, as shown in FIG. 6. The nitride spacer 150a and the nitride spacer material 150b may be removed by performing an etching process P3. The etching process P3 may preferably a wet etching process. In a still preferred embodiment, the wet etching process may be a phosphoric acid and sulfuric acid containing wet etching process, wherein the volume ratio of phosphoric acid and sulfuric acid is 300: 32˜150:300. However, the silicon containing area D, such as the epitaxial layer 160, will also be removed because of a wet etching process containing phosphoric acid and sulfuric acid. Thus, in the present invention, the oxidized surface 20 is formed on the silicon containing area D before the nitride spacer 150a and the nitride spacer material 150 are removed to serve as a protective layer. Therefore, the silicon containing area D can avoid being removed when the nitride spacer 150a and the nitride spacer material 150 are removed by a wet etching process containing phosphoric acid and sulfuric acid. Moreover, the cap layer 128 in this embodiment is a nitride layer, so the exposed cap layer 128 of the first gate G1 will also be removed when the nitride spacer 150a and the nitride spacer material 150 are removed, but it is not limited thereto, depending upon the needs. The etching process P3 can have etching selectivity to the cap layer 128 and the nitride spacer 150a and the nitride spacer material 150b, i.e. the etching rate of the etching process P3 to the cap layer 128 can be different from that of the nitride spacer 150a and the nitride spacer material 150b thanks to carefully selecting the material of the cap layer 128. Therefore, all of, or parts of, the cap layer 128 can be kept.

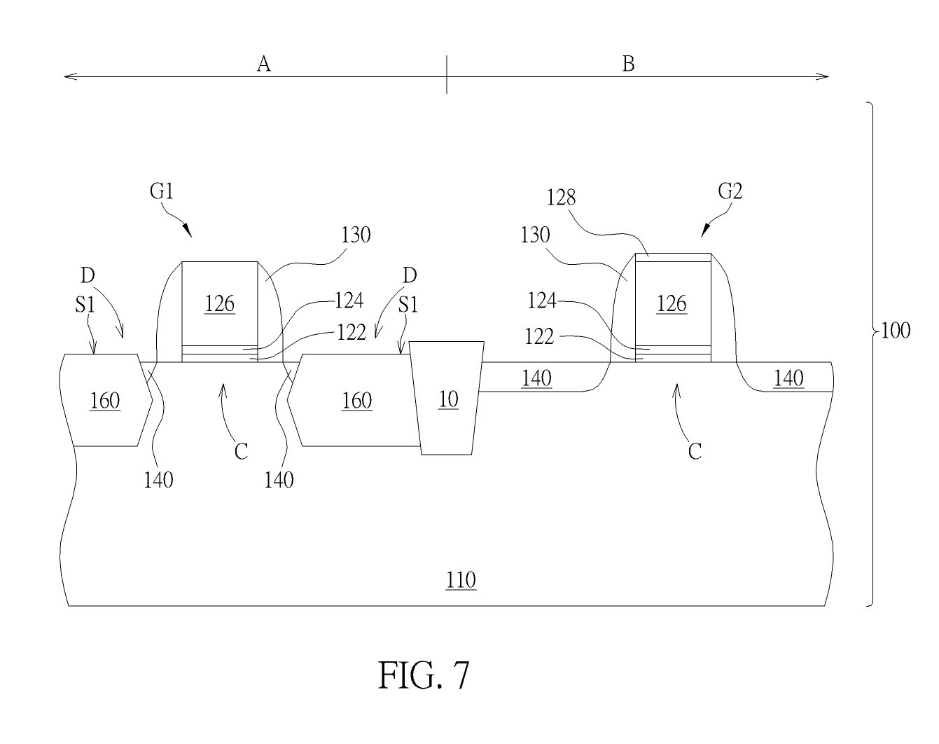

Then, the oxidized surface 20 may be removed as shown in FIG. 7. Therefore, the nitride layer, such as the nitride spacer 150a and the nitride spacer material 150b, can be removed while the silicon substrate 110, such as the silicon containing area D or the epitaxial layer 160, can be maintained through the method presented in the present invention, so the silicon containing area D or the epitaxial layer 160 can avoid being damaged and the performances of a formed semiconductor component can be enhanced. In this embodiment, the method of removing the oxidized surface 20 is reducing the oxidized surface 20. In another embodiment, the oxidized surface 20 may be directly removed by a process such as an etching process.

Thereafter, a later performed semiconductor process may be carried out. For instance, a source/drain region may be formed in the silicon containing area D, a metal silicide may be formed on the source/drain region, a contact etch stop layer may be formed to entirely cover the first area A and the second area B, an interdielectric layer may entirely cover the first area A and the second area B, a metal gate replacement process may be performed to replace the first gate G1 and the second gate G2 by metal gates, contact plugs may be formed on the source/drain region in the interdielectric layer. The method of forming an oxidized surface serving as a protective layer before a nitride layer is removed presented in the present invention can be applied in these semiconductor processes, wherein a nitride layer needs to be removed, such as removing a main spacer for forming a source/drain, removing at least parts of a contact etch stop layer, so that the nitride layer can be removed completely with structures except for the nitride layer that can be kept.

Above all, a CMOS transistor applying the present invention is presented. In the following, an embodiment of forming a MOS transistor by applying the present invention is presented to further illustrate the present invention.

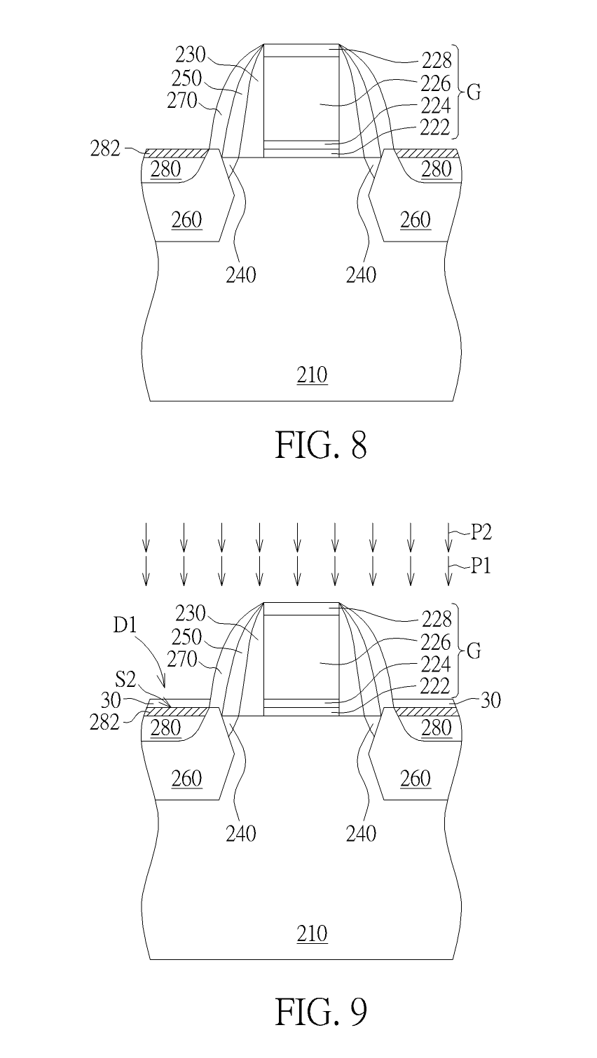

FIGS. 8-10 schematically depict cross-sectional views of a semiconductor process according to a second embodiment of the present invention. As shown in FIG. 8, a gate G is formed on a substrate 210. The gate G may include a buffer layer 222, a gate dielectric layer 124, a barrier layer (not shown), a sacrificial electrode layer 226 and a cap layer 228 from bottom to top. A spacer 230 may be formed on the substrate 220 beside the gate G. A lightly doped source/drain region 240 may be formed in the substrate 210 beside the spacer 230. The methods of forming the gate G, the spacer 230 and the lightly doped source/drain region 240, and the materials of the gate G, the spacer 230 and the lightly doped source/drain region 240 can be associated to the first gate G1, the second gate G2, the spacer 130 and the lightly doped source/drain region 140 of the first embodiment, so as not to describe again.

Then, a nitride spacer 250 is formed on the substrate 210 beside the spacer 230. An epitaxial layer 260 is formed in the substrate 210 beside the nitride spacer 250. The epitaxial layer 260 may be a silicon germanium epitaxial layer, a silicon carbon epitaxial layer or a silicon phosphorus epitaxial layer, depending upon the electrical type of the formed MOS transistor. Thereafter, a main spacer 270 may be selectively formed on the substrate 210 beside the nitride spacer 250. In this embodiment, the main spacer 270 is a nitride spacer that will be removed together with the nitride spacer 250 in a later performed process. A source/drain region 280 may be formed in the substrate 210 beside the main spacer 270. A metal silicide 282 may be selectively formed on the source/drain region 280. This means that the substrate 210 formed as the source/drain region 280 uncovered by the main spacer 270 is a silicon containing area D1 of this embodiment.

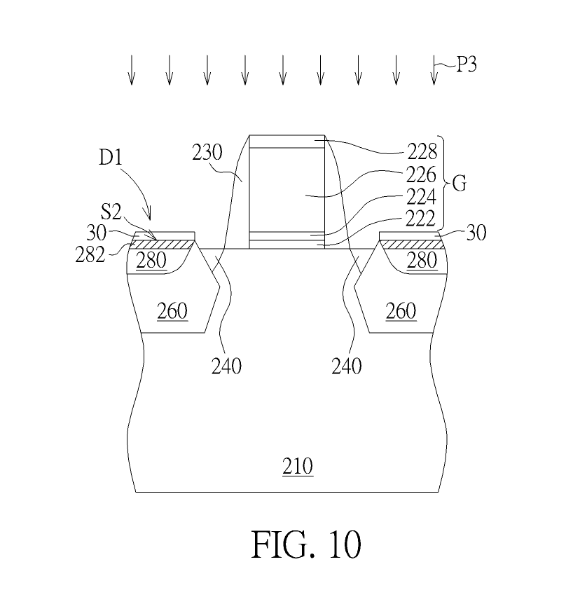

As shown in FIG. 9, a cleaning process P1 may be selectively performed to remove native oxides on the substrate 210. In this embodiment, the cleaning process P1 may be a dilute hydrofluoric acid (DHF) containing cleaning process, but it is not limited thereto. In another embodiment, the cleaning process P1 may be another cleaning process such as a cleaning process with an acid etchant or a cleaning process with an alkaline etchant.

Then, an oxidation process P2 is performed to oxide a surface S2 of the silicon containing area D1, thereby achieving an oxidized surface 30. The oxidation process P2 may be a chemical oxidation process or a thermal oxidation process etc. The oxidation process P2 may be a peroxide containing oxidation process, an ozone containing oxidation process or a plasma oxygen containing oxidation process etc. The oxidized surface 30 can be formed by oxidizing the surface S2 of the silicon containing area D1 without oxidizing areas other than silicon containing area D1 such as the nitride spacer 250 and the main spacer 270 through selecting the oxidation process P2. In this embodiment, the oxidized surface 30 is formed by oxidizing the surface S2 of the silicon containing area D1. In another embodiment, the oxidized surface 30 may be directly formed on the silicon containing area D1 without oxidizing it.

The nitride spacer 250 and the main spacer 270 may be removed as shown in FIG. 10. The method of removing the nitride spacer 250 and the main spacer 270 may include performing an etching process P3. The etching process P3 is preferably a wet etching process. In a still preferred embodiment, the wet etching process may be a wet etching process containing phosphoric acid and sulfuric acid. It is emphasized that residues of the nitride spacer 250 and the main spacer 270 may remain because of a bad etching by a wet etching process containing only phosphoric acid. However, the silicon containing area D1 will also be removed by over-etching with a wet etching process containing a phosphoric acid and sulfuric acid.

In the present invention, since the oxidized surface 30 is formed on the silicon containing area D1 before the nitride spacer 150a and the main spacer 270 are removed for serving as a protective layer. Therefore, the silicon containing area D1 can avoid being removed when the nitride spacer 150a and the main spacer 270 are removed by a wet etching process containing phosphoric acid and sulfuric acid. Moreover, all of, or parts of, the cap layer 228 can be kept through selecting the etching selectivity of the etching process P3 to the cap layer 128 and the nitride spacer 250 and the main spacer 270. Then, the oxidized surface 30 may be removed. The method of removing the oxidized surface 30 may be reducing the oxidized surface 30 or removing the oxidized surface 30 by a process such as an etching process.

According to the above, the present invention can be applied to various processing steps desired to remove nitride layers. For example, after a lightly doped source/drain region, an epitaxial layer or a source/drain region is formed by a nitride spacer, the nitride spacer would be removed; a nitride contact etch stop layer or a nitride stress layer would be removed; a hard mask or an etch stop layer etc would be removed after a material layer is patterned. The silicon containing areas may be areas other than the nitride layers, such as a lightly doped source/drain region, an epitaxial layer, a source/drain region or a metal silicide.

Furthermore, the present invention can be applied to non-planar transistors, such as multi-gate MOSFETs, or other planar transistors. For instance, the present invention can be applied to a tri-gate MOSFET. In this case, a fin-shaped structure is formed on a substrate; a gate is formed across the fin-shaped structure and the substrate. A spacer is formed across the fin-shaped structure and substrate beside the gate. A lightly doped source/drain region, an epitaxial layer and or a source/drain region may be formed in the fin-shaped structure beside the spacer by various processing orders. Although non-planar transistors have different structures from planar transistors, they have processing methods similar to those of planar transistors. Therefore, the method of the present invention in the first embodiment and the second embodiment can also be applied to non-planar transistors, so as not to describe again.

To summarize, the present invention provides a semiconductor process, which performs an oxidation process before removing a nitride layer to oxide a silicon containing area other than the nitride layer. Therefore, an oxidized surface is formed on the silicon containing area serving as a protective layer to prevent the silicon containing area from being damaged while removing the nitride layer. Then, the oxidized surface is removed for performing semiconductor processes thereafter.

Moreover, the oxidation process may be a chemical oxidation process. The oxidation process may be a peroxide containing oxidation process, an ozone containing oxidation process or a plasma oxygen containing oxidation process etc. The method of removing the nitride layer may include performing a wet etching process. The wet etching process may be a phosphoric acid and sulfuric acid containing etching process. Furthermore, the present invention can applied to non-planar or planar semiconductor structures such as a non-planar or planar semiconductor structure of a MOS transistor or a CMOS transistor.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor process, comprising:
providing a substrate;
forming a nitride layer on the substrate but exposing a silicon containing area of the substrate;
performing an oxidation process to oxidize a surface of the silicon containing area to form an oxidized surface;
removing the nitride layer;
removing the oxidized surface of the silicon containing area right after the nitride layer is removed; and
forming a source/drain region in the silicon containing area after the oxidized surface is removed.

2. The semiconductor process according to claim 1, wherein the oxidation process comprises a chemical oxidation process.

3. The semiconductor process according to claim 1, wherein the oxidation process comprises a peroxide containing oxidation process, an ozone containing oxidation process or a plasma oxygen containing oxidation process.

4. The semiconductor process according to claim 1, wherein the nitride layer comprises a nitride spacer.

5. The semiconductor process according to claim 4, wherein the steps of forming the nitride layer comprise:
forming a gate on the substrate; and
forming the nitride spacer on the substrate beside the gate.

6. The semiconductor process according to claim 5, wherein the top of the gate comprises a cap layer, and the step of removing the nitride layer comprises removing the cap layer.

7. The semiconductor process according to claim 4, wherein the steps of forming the nitride layer comprise:
forming a first gate and a second gate on the substrate;
forming a nitride spacer material to cover the first gate, the second gate and the substrate entirely; and
etching the nitride spacer material covering the first gate and the substrate beside the first gate to form the nitride spacer but keeping the nitride spacer material covering the substrate beside the second gate and the second gate.

8. The semiconductor process according to claim 7, wherein the step of removing the nitride layer comprises:
removing the nitride spacer material and the nitride spacer.

9. The semiconductor process according to claim 8, wherein the top of the first gate comprises a cap layer, and the step of removing the nitride layer comprises removing the cap layer.

10. The semiconductor process according to claim 7, wherein the first gate comprises a gate of a PMOS transistor and the second gate comprises a gate of an NMOS transistor.

11. The semiconductor process according to claim 1, wherein a method of removing the nitride layer comprises performing a wet etching process.

12. The semiconductor process according to claim 11, wherein the wet etching process comprises an etching process containing phosphoric acid and sulfuric acid.

13. The semiconductor process according to claim 1, wherein the silicon containing area comprises an epitaxial layer.

14. The semiconductor process according to claim 13, wherein the epitaxial layer comprises a silicon germanium epitaxial layer.

15. The semiconductor process according to claim 1, wherein the silicon containing area comprises a source/drain region.

16. The semiconductor process according to claim 15, wherein the source/drain region has a metal silicide formed thereon.

17. The semiconductor process according to claim 1, further comprising:
performing a cleaning process before the oxidation process is performed to remove native oxides on the substrate and the nitride layer.

18. The semiconductor process according to claim 17, wherein the cleaning process comprises a dilute hydrofluoric acid (DHF) cleaning process.

19. (canceled)

20. The semiconductor process according to claim 19, wherein the method of removing the oxidized surface comprises reducing the oxidized surface.
